(19) United States
(12) Patent Application Publication
(10) Pub. No.: US 2026/0149427 A1
(43) Pub. Date: May 28, 2026

(54) SYSTEM FOR EXTENDING AUDIO DYNAMIC RANGE USING TWO-CHANNEL ANALOG-TO-DIGITAL CONVERTERS

(71) Applicant: Harman International Industries, Incorporated, Stamford, CT (US)

(72) Inventors: Ruihua CHEN, Shenzhen (CN); Ruiting YANG, Rostrevor (AU); Hesheng BAO, Shenzhen (CN); Yuanru DUAN, Shenzhen (CN)

(21) Appl. No.: 18/958,343

(22) Filed: Nov. 25, 2024

(51) Int. Cl. H03G 7/00; H03G 3/30

(52) U.S. Cl. CPC H03G 7/007; H03G 3/3005

(57) ABSTRACT

An audio processing system includes an audio source device configured to provide an analog based audio signal; an audio converting device including an analog gain amplifier configured to amplify the analog based audio signal into an amplified analog signal, a first analog-to-digital converter (ADC) configured to convert the amplified analog signal into an amplified digital signal, a digital gain reducer configured to reduce the amplified digital signal into a first digital signal, an analog gain reducer configured to reduce the analog based audio signal into a reduced analog signal, a second ADC configured to convert the reduced analog signal into a reduced digital signal, and a digital gain amplifier configured to amplify the reduced digital signal into a second digital signal.

### TECHNICAL FIELD

The present disclosure generally relates to a system for processing audio signals. More specifically, the present disclosure relates to a system for extending a dynamic range of an audio signal using two-channel analog-to-digital converters (ADCs).

### BACKGROUND

Dynamic range in audio signals refers to the ratio of maximum signal level and minimum signal level in volume. The minimum input signal level may be determined by the noise of the system, and the maximum input signal level may be limited a relatively large value that will not cause system distortion. A wide dynamic range may be desirable as it enable the audio system to capture and record both low and high volume sounds without distortion or loss of detail. The dynamic range may be defined by the performance of the ADC of the audio system. A well-configured ADC may be associated with low noise and high input volume without causing distortion. However, in the conventional approach, the ADC performance is preconfigured which limits the dynamic range of the audio system.

### SUMMARY

In one or more exemplary embodiments of the present disclosure, an audio processing system includes an audio source device configured to provide an analog based audio signal; an audio converting device including an analog gain amplifier configured to amplify the analog based audio signal into an amplified analog signal, a first analog-to-digital converter (ADC) configured to convert the amplified analog signal into an amplified digital signal, a digital gain reducer configured to reduce the amplified digital signal into a first digital signal, an analog gain reducer configured to reduce the analog based audio signal into a reduced analog signal, a second ADC configured to convert the reduced analog signal into a reduced digital signal, and a digital gain amplifier configured to amplify the reduced digital signal into a second digital signal.

In one or more exemplary embodiments of the present disclosure, a computer-program product embodied in a non-transitory computer read-able medium that is programmed and executable by one or more controllers to process an audio input signal, the computer-program product includes instructions for amplifying an analog audio signal of the audio input signal into an amplified analog signal, converting the amplified analog signal into an amplified digital signal, reducing the amplified digital signal into a first digital signal, reducing the analog audio signal into a reduced analog signal, converting the reduced analog signal into a reduced digital signal, and amplifying the reduced digital signal into a second digital signal.

In one or more exemplary embodiments of the present disclosure, a method for processing an audio input signal, the method includes amplifying an analog signal of the audio input signal into an amplified analog signal; converting the amplified analog signal into an amplified digital signal; reducing the amplified digital signal into a first digital signal; reducing the analog signal into a reduced analog signal; converting the reduced analog signal into a reduced digital signal; amplifying the reduced digital signal into a second digital signal; and combining the first digital signal and the second digital signal into a combined digital signal.

### BRIEF DESCRIPTION OF THE DRAWINGS

For a better understanding of the invention and to show how it may be performed, embodiments thereof will now be described, by way of non-limiting example only, with reference to the accompanying drawings, in which:

FIG. 1 illustrates an example block topology of an audio system of one embodiment of the present disclosure.

FIG. 2 illustrates an example block diagram of an audio system utilizing two ADCs of one embodiment of the present disclosure.

FIG. 3 illustrates a graph of a tunable parameter associated with weights based on root mean square of one embodiment of the present disclosure.

FIG. 4 illustrates an example flow diagram of a process for operating the vehicle system of one embodiment of the present disclosure.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure, among other things, proposes a system for processing audio signals with extended audio dynamic range. More specifically, the present disclosure proposes a system for extending a dynamic range of an audio signal using two-channel ADCs.

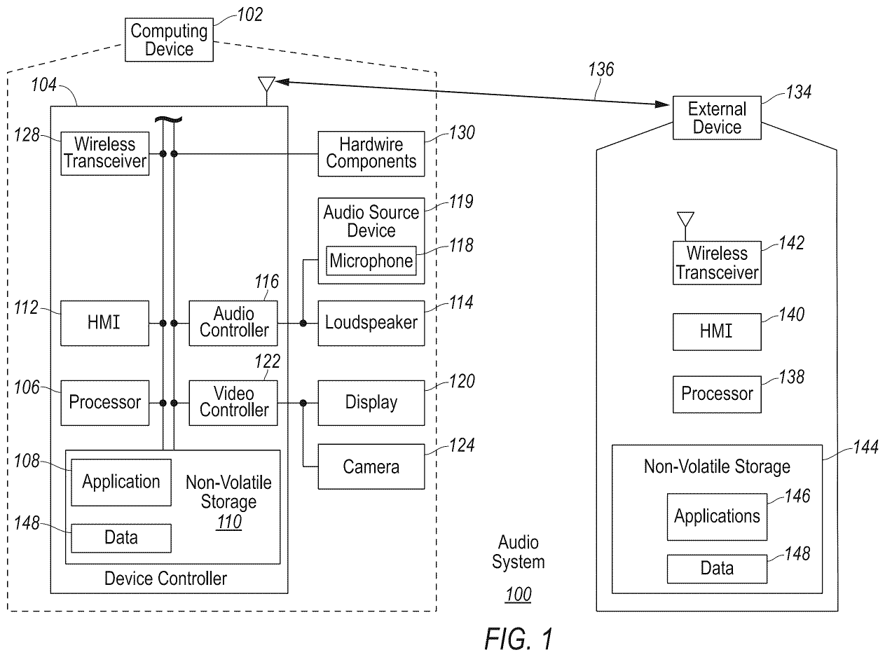

Referring to FIG. 1, an example block diagram of an audio system 100 involving one or more devices of one or more embodiments of the present disclosure is illustrated. The audio system 100 may be applied to various indoor, outdoor and/or automobile situations such as home theater, karaoke, meeting presentations, automobile infotainment system or the like, configured to capture audio signals and/or provide audio sounds within a designated area such as a room and/or vehicle cabin. The audio system 100 may be associated with one or more computing devices 102 configured to perform various operations with regard to the audio input and/or output within the designated area. For simplicity, only one computing device 102 is shown in FIG. 1.

As illustrated in FIG. 1, the computing device 120 may be provided with a device controller 104 configured to provide various functions. The device controller 104 may include one or more processors 106 configured to perform instructions, commands, and other routines in support of the processes described herein. For instance, the primary device controller 104 may be configured to execute instructions of device applications 108 to provide features such as audio input, audio output, analog-to-digital conversion, digital-to-analog conversion, remote communication, audio blending/adjustment or the like. Such instructions and other data may be maintained in a non-volatile manner using a variety of types of computer-readable storage medium 110. The computer-readable storage medium 110 (also referred to as a processor-readable medium or storage) may include any non-transitory medium (e.g., tangible medium) that participates in providing instructions or other data that may be read by the processor 106 of the primary device controller 104. Computer-executable instructions may be compiled or interpreted from computer programs created using a variety of programming languages and/or technologies, including, without limitation, and either alone or in combination, Java, C, C++, C #, Objective C, Fortran, Pascal, Java Script, Python, Perl, and structured query language (SQL).

The device controller 104 may be provided with various features allowing the users to interface with the computing device 102. For instance, the primary device controller 104 may receive input from human machine interface (HMI) controls 112 configured to provide for user interaction with the computing device 102. As an example, the device controller 104 may interface with one or more buttons, touch sensors, knobs or other HMI controls configured to invoke functions on the computing device 102.

The device controller 104 may be operably connected to one or more loudspeakers 114 configured to provide audio output to the users by way of an audio interface 116. The audio interface 116 may be configured to perform various operations such as digital-to-analog conversions to convert audio signals in digital forms into analog forms for output.

The device controller 104 may also be operably connected to one or more audio source devices 119 configured to provide input to the primary device controller 104 by way of the audio interface 116. In one or more examples, the audio source devices 119 may include one or more microphones 118. Additionally or alternatively, the audio source devices 119 may be configured to receive audio signal elsewhere (e.g., from a radio signal). The audio interface 116 may be configured to perform various operations such as analog-to-digital conversions to convert audio signals in analog forms into digital forms for storage and/or processing.

The device controller 104 may also be operably connected to one or more displays 120 configured to provide visual output to the users by way of a video interface 122. In some cases, the display 120 may be a touch screen further configured to receive user touch input via the video interface 122, while in other cases the display 120 may be a display only, without touch input capabilities. The primary device controller 104 may also drive or otherwise communicate with one or more cameras 124 configured to provide video input to the primary device controller 104 by way of the video interface 122.

The device controller 104 may be configured to wirelessly communicate with various entities to enable various functions. As discussed above, the device controller 104 may enable the wireless communication between the computing device 102 and one or more external devices 134 via one or more wireless connections 136 by way of the wireless transceiver 128. The external device 134 may be any of various types of portable and/or stationary computing devices, such as cellular phones, tablet computers, wearable devices, smart watches, laptop computers, portable music players, wireless speakers, wireless microphones, television, or a set-top box (STB) or other devices capable of communication with the device controller 104.

The wireless transceiver 128 may be in communication with one or more controllers (not shown) in support of various communication protocols to facilitate the above wireless connections 136. For instance, the wireless transceiver 128 may be in communication with a Wi-Fi controller in support of various protocols of IEEE 802.11 family, a near-field communication (NFC) controller in support of NFC protocols, a Bluetooth controller in support of Bluetooth Classic and/or Bluetooth Low Energy protocols, a radio-frequency identification (RFID) controller in support of RFID protocols, and/or other controllers and configured to communicate with one or more compatible wireless transceivers the various entities connected to the primary device controller 104.

The external device 134 may be provided with a processor 138 configured to perform instructions, commands, and other routines in support of the processes such as navigation, telephone, wireless communication, and multi-media processing depending on the specific identity of the external device 134. The external device 134 maybe further provided with HMI controls 140 configure to provide user interaction with the external device 134. For instance, the external device 134 may interface with one or more buttons, touch screens, or other HMI controls configured to invoke functions on the external device 134 as well as function on the device controller 104 (e.g. audio volume control, audio settings). The external device 134 may be provided with a wireless transceiver 142 in communication with various controllers (not shown) and configured to communicate with the wireless transceiver 128 of the primary device controller 104.

The mobile device 134 may be further provided with a non-volatile storage 144 to store various applications 146 to enable various operations. Among other things, the applications 146 may allow the user to interact the audio system 100 via the computing device 102 through the wireless connection 136.

The device controller 104 may further be operably connected to one or more hardware components 130 of the computing device 102 configured to perform various operations. The hardware components 130 may include various hardware devices, apparatus, controllers, processors or the like. For instance, the hardware components 130 may include one or more lights (e.g., LEDs) configured to turn on and off based on the control signals from the device controller 104. The hardware components 130 may further include one or more vibrators configured to provide haptic feedback based on the control signals from the device controller 104. The hardware components 130 may further include one or more controller devices configured perform various controls based on the specific applications. For instance, when applied to a vehicle/automobile, the hardware components 130 may include one or more controllers configured to operate the vehicle functions such as autonomous driving, vehicle heating, ventilation, and air conditioning (HVAC) controls, vehicle light controls, vehicle seat controls, vehicle radio/infotainment system controls or the like.

It is noted that although the device controller 104 is integrated with the computing device 102 in the example illustrated with reference to FIG. 1, the present disclosure is not limited thereto. In one or more alternative examples, the device controller 104 may be entirely or partially implemented external to the computing device. As a few non-limiting examples, the device controller 104 may be entirely or partially implemented as a standalone device (e.g., a tablet computer) in communication with the computing device 102. Additionally or alternatively, the device controller 104 may be entirely or partially implemented via the external device. Additionally or alternatively, the primary device controller 104 may be entirely or partially implemented in a cloud-based manner via a server remotely connected to the audio system 100 via a public and/or private network (e.g., through Internet).

It is further noted that although the various components of the audio system 100 are connected wirelessly in the example illustrated with reference to FIG. 1, the present disclosure is not limited thereto. In one or more alternative examples, one or more of the components of the audio system 100 may be connected to each other in a wired manner using cables and harnesses. For instance, data communication between the components of the audio system 100 may be established using one or more of a universal serial bus (USB) interface, RJ45 ethernet connector, powerline communication (PLC) interface or the like.

As discussed above, the conventional approach utilizes a single the ADC with preconfigured performance that may limit the dynamic range of the audio system. More specifically, the dynamic range of an ADC may be determined by its quantization noise which represents the minimum input level, and full-scale voltage which represents the maximum input level. For a given system, the quantization noise may depend on the number of quantization bits, therefore the level of quantization noise may be fixed. For instance, analog audio signal with low amplitude (e.g., loudness) is naturally affected by the quantization noise more, as a low signal to noise ratio (SNR) may cause loose details of a sound. In this case, amplifying the signal before ADC may increase the SNR of the analog audio signal. Conversely, when the analog audio signal amplitude (e.g., loudness) is high, the quantization noise may be considered as negligible, but a large value of signal level may exceed the maximum value of the quantization bits supported by the ACD, and thus cause clipping and distortion. In this case, reducing the gain of the analog audio signal before ADC may lower signal below the full-scale voltage.

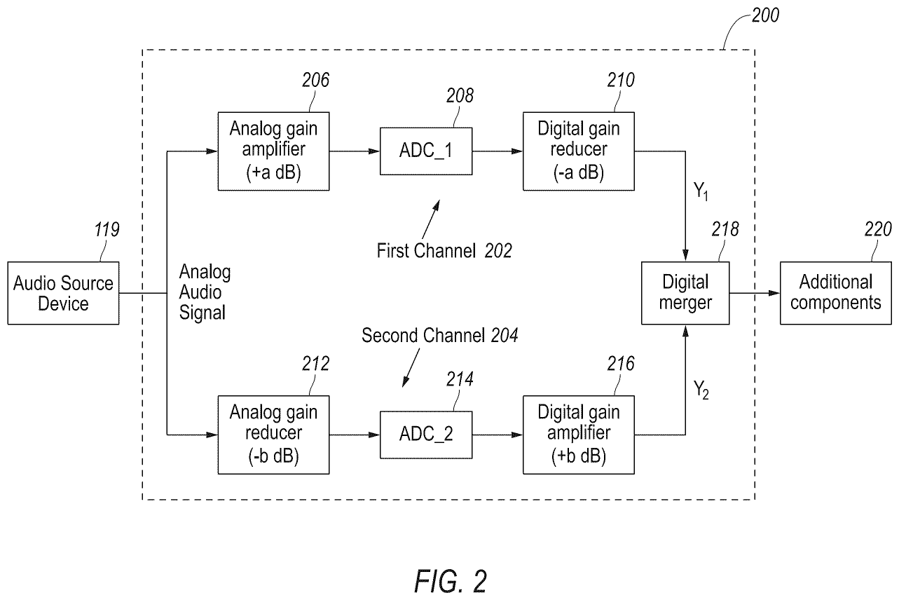

The present disclosure proposes an audio system with extended audio dynamic range by utilizing multiple ADCs. Referring to FIG. 2, an example block diagram of an audio converting system 200 utilizing two ADCs of one embodiment of the present disclosure is illustrated. With continuing reference to FIG. 1, the audio converting system 200 may be completely or partially implemented via the computing device 102.

The audio converting system 200 may operably connected to one or more audio source devices 119 configured to collect and/or provide an analog audio signal to the audio converting system 200. For instance, one or more microphones 118 may be configured to function as the audio source device 119 in the present example. The microphone may be configured to collect audio input (e.g., a voice input from a user) into the analog audio signal. More specifically, when sound waves hit a diaphragm of the audio source device 119, the sound waves cause the diaphragm to vibrate. The vibration is then converted to an analog electrical signal (e.g., the analog audio signal). In one or more alternative example, the other devices may be used to function as the audio source device in addition to and/or in lieu of the audio source device 119. For instance, audio converting system 200 may receive a prerecorded analog audio signal from one or more storage devices and/or radio devices.

The audio converting system 200 may include a first channel 202 and a second channel 204 for individually converting the analog audio signal output from the audio source device 119 into digital forms. More specifically, the first channel 202 may be configured to optimize the analog-to-digital conversion of audio signals having low amplitude (e.g., low volume) while the second channel 204 may be configured to optimize the analog-to-digital conversion of audio signals having high amplitude (e.g., high volume).

The first channel 202 may include a variety of components. For instance, the first channel 202 may include an analog gain amplifier 206 configured to increase the strength of input analog audio signal and output an amplified analog audio signal. The gain may be measured in units of decibels (dB). The analog gain amplifier 206 may increase the signal strength of portions of the audio signal having a low amplitude such that portions may be better processed in subsequent stages. The analog gain amplifier 206 may be configured to increase the gain of the analog audio signal by a predetermined amount (e.g., +a dB).

Following the analog gain amplifier 206, the first channel 202 may further include a first ADC 208 configured to convert the amplified analog audio signal into a digital signal. For instance, the first ADC 208 may perform the analog-to-digital conversion by sampling the amplified analog audio signal at a regular interval and then quantizing sampled values into discrete levels. The discrete levels may than be encoded into one or more binary sequence in forms of digital data.

Since the analog audio signal has been amplified by the analog gain amplifier 206 before being provided to the first ADC 208, the digital signal output from the first ADC 208 is associated with amplified levels and may need to be restored to the original level before further processing. Therefore, the first channel 202 may further include a digital gain reducer 210 configured reduce the gain of the digital signal output by the first ADC 208. The digital gain reducer 210 may be configured to reduce the gain of the digital audio signal by a predetermined amount (e.g., −a dB) which corresponds to the amplified amount by the analog gain amplifier 206. The digital gain reducer 210 may perform the gain reduction by mapping the digital levels of the digital signal to other values using a look-up-table such that the reduced digital signal corresponds to the original analog audio signal. In the present disclosure, the gain-reduced digital signal (first digital signal) output by the digital gain reducer 210 may be represented as y₁.

The second channel 204 may include similar configurations to those of the first channel 202 except that it aims to optimize the analog-to-digital conversion of audio components associated with high amplitudes. The second channel 204 may include an analog gain reducer 212 configured to reduce the strength of input analog audio signal and output a reduced analog audio signal. The analog gain reducer 212 may reduce the signal strength of portions of the audio signal having a high amplitude such that portions may be better processed in subsequent stages. The analog gain reducer 212 may be configured to reduce the gain of the analog audio signal by a predetermined amount (e.g., −b dB). It is noted that gain reduction magnitude (e.g., −b dB) achieved by the analog gain reducer 212 may not be equal or unequal to the gain amplification magnitude (e.g., +a dB) achieved by the analog gain amplifier 206 in the present example.

It is further noted that, in one example, the gain amplification/reduction magnitudes (e.g., a and b) of both the first channel 202 and the second channel 204 may be predetermined. In an alternative example, the gain amplification/reduction magnitudes (e.g., a and b) may be variable and dynamically determined by one or more factors. For instance, the gain amplification magnitudes (e.g., a) of the first channel 202 may be inversely proportional to the amplitude of the analog audio signal. E.g., a low amplitude audio signal may result in a greater gain amplification whereas a high amplitude audio signal may result in a lesser gain amplification by the analog gain amplifier 206. The gain reduction magnitudes (e.g., b) of the second channel 204 may be proportional to the amplitude of the analog audio signal. E.g., a low amplitude audio signal may result in a lesser gain reduction whereas a high amplitude audio signal may result in a greater gain reduction by the analog gain reducer 212.

Following the analog gain reducer 212, the second channel 204 may further include a second ADC 214 configured to convert the reduced analog audio signal into a digital signal. Here, the second ADC 214 may be configured in a similar manner to the first ADC 208 and therefore the detail operations will not be repeated herein.

Since the analog audio signal has been reduced by the analog gain reducer 212 before being provided to the second ADC 214, the digital signal output from the second ADC 214 is associated with amplified levels and may need to be restored to the original level before further processing. Therefore, the second channel 204 may further include a digital gain amplifier 216 configured amplify the gain of the digital signal output by the second ADC 214. The digital gain amplifier 216 may perform the gain amplification to increase the gain of the gain-reduced digital signal output from the second ADC 214 such that the amplified digital signal corresponds to the original analog audio signal. The digital gain amplifier 216 may be configured to amplify the gain of the digital audio signal by a predetermined amount (e.g., +b dB) which corresponds to the reduced amount by the analog gain reducer 212. In the present disclosure, the gain-increase digital signal (second digital signal) output by the digital gain amplifier 216 may be represented as y₂.

The audio converting system 200 may further include a digital merger 218 configured to merge/combine the gain-reduced digital signal y₁ output by the first channel 202 and the gain-increase digital signal y₂ output by the second channel 204 into a combined digital signal y. The combined digital signal y output by the digital merger 218 may be expressed in the following equation:

$$y = α {y}_{1} + β {y}_{2} \qquad ( 1 )$$

wherein α and β denote the weights of the signal level for the first digital signal y₁ and the second signal y₂ respectively. There are a variety of methods in which the weights α and β may be determined. For instance, the weights α and β may be determined using the root mean square (RMS) value of a frame of signal. For a fame of signal yᵢ, wherein i=1, 2, with K samples, the RMS value may be determined by:

$${R}_{i} = \sqrt[2]{\frac{1}{K} {\sum }_{k = 1}^{K} {\vert {y}_{i} [ k ] \vert}^{2} 2} \qquad ( 2 )$$

The first weight α for the first digital signal y₁ may be determined by:

$$α = f ( {R}_{1} ) = \frac{{e}^{- ( {R}_{1} - {R}_{0} )}}{1 + {e}^{- ( {R}_{1} - {R}_{0} )}} \qquad ( 3 )$$

The second weight β for the second digital signal y₂ may be determined by:

$$β = f ( {R}_{2} ) = \frac{1}{1 + {e}^{- ( {R}_{2} - {R}_{0} )}} \qquad ( 4 )$$

In the above equations, the sum of the first weight α and the second weight β is equal to 1. In addition, R₀ is a tunable parameter when first weight α and the second weight β are equal. E.g., α=β=0.5.

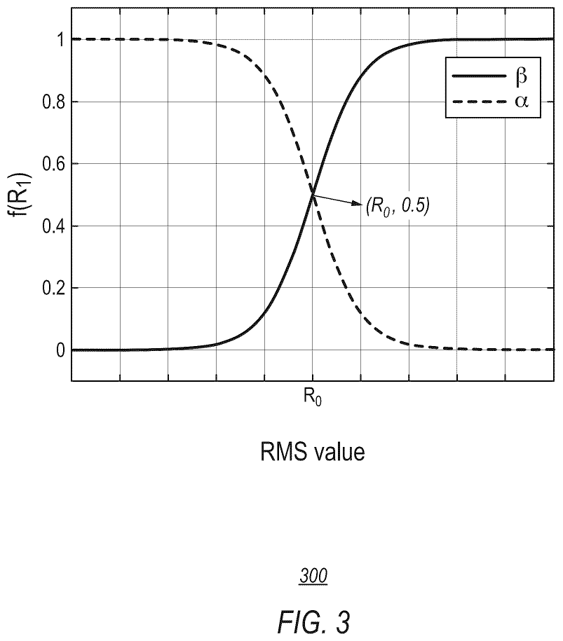

To better illustrate the tunable parameter R₀, FIG. 3 illustrates a graph 300 of a tunable parameter associated with weights based on root mean square of one embodiment of the present disclosure. In the graph 300, the horizontal axis is representative of the RMS values calculated based on equation (2), and the vertical axis is representative of the weights calculated by equations (3) and (4).

In the present example, the graph 300 illustrates both the first weight α in a dash line, and the second weight β in solid line. As illustrated, the first weight α is associated with the highest value (e.g., 1) when the RMS values is at the minimum level corresponding to the minimum amplitude of the analog audio signal (e.g., minimum volume). As the RMS values increases, the first weight α reduces. The first weight α is associated with the lowest value (e.g., 0) when the RMS values reaches the maximum corresponding to a very high amplitude of the analog audio signal (e.g., volume very loud).

The second weight β exhibits characteristics opposite to those of the first weight α. The second weight β is associated with a low value (e.g., 0) when the RMS values is at the minimum level corresponding to the lowest amplitude of the analog audio signal supported by the audio system 100 (e.g., minimum volume). As the RMS values increases, the second weight β increases. The second weight β is associated with a high value (e.g., 1) when the RMS values reaches the maximum corresponding to the highest amplitude of the analog audio signal (e.g., maximum volume).

The tunable parameter R₀ may be set to the level when the waves of first weight α and the second weight β cross. In the present example, the waves cross at the weight f(Ri) is at 0.5 (e.g., α=β=0.5).

After a successful digital signal combination, the combined digital signal y may be provided to one or more additional components 220 of the audio system 100 for further processing. The additional components 220 may include various examples applicable to different situations. For instance, the additional components 220 may include a storage 110 to store the digital signal y in a non-volatile manner for future use. Additionally or alternatively, the additional components 220 may include one or more wireless transceivers 128 configured to send the digital signal y to one or more external devices 134. Additionally or alternatively, the additional components 220 may include one or more processors 106 configured to perform operations such as voice recognition to the digital signal y. For instance, the digital signal y may include one or more voice commands. Responsive to a successful recognition, the computing device 102 may perform further operations based on the recognized voice command.

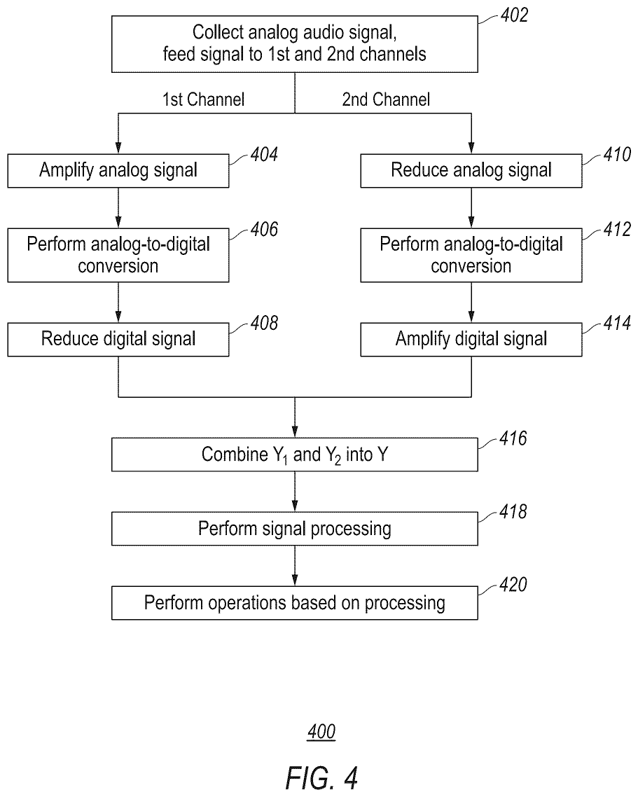

Referring to FIG. 4, an example flow diagram of a process 400 for operating the audio system of one embodiment of the present disclosure is illustrated. With continuing reference to FIGS. 1-3, the operations of the process 400 may be completely or partially implemented via the audio converting system 200 and/or the computing device 102. For simplicity, the following description will be made with reference to the audio converting system 200 and the computing device 102.

At operation 402, the computing device 102 collects an analog audio signal via one or more audio source devices and feeds the audio signal to both the first channel 202 and the second channel 204 for processing. As discussed above, the audio source devices may be implemented in various manners. In a non-limiting example, the audio source devices 119 may be implemented via one or more microphones 118 of the computing device 102 configured to collect the analog audio signal (e.g., a user voice).

With the first channel 202 configured to optimize the analog-to-digital conversion of audio signals having low amplitude (e.g., low volume), at operation 404, the analog gain amplifier 206 amplifies the analog signal and increase the gain of the signal by an amount (e.g., +a dB). As discussed above, the magnitude of gain amplitude may be predetermined. Alternatively, the magnitude of gain amplitude may be dynamically adjusted by factors such as the amplitude of the analog audio signal

At operation 406, the first ADC 208 of the first channel 202 converts of the amplified analog signal into an amplified digital signal.

At operation 408, the digital gain reducer 210 of the first channel 202 reduces the gain of the amplified digital signal by the corresponding amount (e.g., −a dB) such that the gain of the digital signal y₁ is restored to the original level.

With the second channel 204 configured to optimize the analog-to-digital conversion of audio signals having high amplitude (e.g., high volume), at operation 410, the analog gain reducer 212 reduces the analog signal and reduce the gain of the signal by an amount (e.g., −b dB). Similarly, the magnitude of gain reduction may be predetermined. Alternatively, the magnitude of gain reduction may be dynamically adjusted by factors such as the amplitude of the analog audio signal.

At operation 412, the second ADC 208 of the second channel 204 converts of the reduced analog signal into a reduced digital signal.

At operation 414, the digital gain amplifier 216 of the second channel 204 amplifies the gain of the reduced digital signal by the corresponding amount (e.g., +b dB) such that the gain of the digital signal y₂ is restored to the original level.

At operation 416, the digital merger 218 combines the first digital signal y₁ from the first channel 202 and the second digital signal y₂ from the second channel 204 into a combined digital signal y. As discussed above, the RMS may be used to facilitate the combination.

At operation 418, the device controller 104 processes the combined digital signal y. For instance, digital signal y may include one or more voice commands. The device controller 104 may perform voice recognition on the digital signal y to determine the one or more voice commands.

At operation 420, the device controller 104 performs further operations based on the result of the signal processing. Continuing with the above voice command example, the device controller 104 may perform one or more operations via a corresponding device to implement the voice command. For instance, responsive to determine the voice command, the device controller 104 may operate the one or more hardware components 130 to perform various operations such as turning on/off a light, providing haptic feedback, changing radio channel, changing HVAC setting or the like as supported by the hardware components. Additionally or alternatively, the system executes one of the voice command to playback an audio input signal into a listening environment as the operation.

It is recognized that the controllers as disclosed herein may include various microprocessors, integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, such controllers as disclosed utilizes one or more microprocessors to execute a computer-program that is embodied in a non-transitory computer readable medium that is programmed to perform any number of the functions as disclosed. Further, the controller(s) as provided herein includes a housing and the various number of microprocessors, integrated circuits, and memory devices ((e.g., FLASH, random access memory (RAM), read only memory (ROM), electrically programmable read only memory (EPROM), electrically erasable programmable read only memory (EEPROM)) positioned within the housing. The controller(s) as disclosed also include hardware-based inputs and outputs for receiving and transmitting data, respectively from and to other hardware-based devices as discussed herein.

While exemplary embodiments are described above, it is not intended that these embodiments describe all possible forms encompassed by the claims. The words used in the specification are words of description rather than limitation, and it is understood that various changes may be made without departing from the spirit and scope of the disclosure. The words processor and processors may be interchanged herein, as may the words controller and controllers.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. An audio processing system comprising:
an audio source device configured to provide an analog based audio signal;
an audio converting device including:
an analog gain amplifier configured to amplify the analog based audio signal into an amplified analog signal,
a first analog-to-digital converter (ADC) configured to convert the amplified analog signal into an amplified digital signal,
a digital gain reducer configured to reduce the amplified digital signal into a first digital signal,
an analog gain reducer configured to reduce the analog based audio signal into a reduced analog signal,
a second ADC configured to convert the reduced analog signal into a reduced digital signal, and
a digital gain amplifier configured to amplify the reduced digital signal into a second digital signal.

2. The system of claim 1, wherein the audio converting device further comprising:
a digital merger configured to combine the first digital signal and the second digital signal into a combined digital signal.

3. The system of claim 2, wherein the digital merger combines the first digital signal and the second digital signal using a root mean square (RMS) value of a frame signal.

4. The system of claim 2 further comprising:
one or more controllers programed to process the combined digital signal; and
responsive to processing the combined digital signal, perform an operation on the system.

5. The system of claim 4, wherein the combined digital signal is indicative of one of a voice command and an audio input signal, and the system executes one of the voice command as the operation and processing the audio input signal to playback the audio input signal into a listening environment as the operation.

6. The system of claim 1, wherein the analog gain amplifier is further configured to amplify the analog based audio signal by a first gain value; and the analog gain reducer is configured to reduce the analog based audio signal by a second gain value different from the first gain value.

7. The system of claim 6, wherein the first gain value is inversely proportional to an amplitude estimate of the analog based audio signal.

8. The system of claim 6, wherein the second gain value is proportional to an amplitude estimate of the analog based audio signal.

9. A computer-program product embodied in a non-transitory computer read-able medium that is programmed and executable by one or more controllers to process an audio input signal, the computer-program product comprising instructions for:
amplifying an analog audio signal of the audio input signal into an amplified analog signal,
converting the amplified analog signal into an amplified digital signal,
reducing the amplified digital signal into a first digital signal,
reducing the analog audio signal into a reduced analog signal,
converting the reduced analog signal into a reduced digital signal, and
amplifying the reduced digital signal into a second digital signal.

10. The computer-program product of claim 9, wherein the computer-program product further comprising instructions for:
combining the first digital signal and the second digital signal into a combined digital signal.

11. The computer-program product of claim 10, wherein the computer-program product further comprising instructions for:
combining the first digital signal and the second digital signal using a root mean square (RMS) value of a frame signal.

12. The computer-program product of claim 10, wherein the computer-program product further comprising instructions for:
processing the combined digital signal; and
responsive to processing the combined digital signal, performing an operation on a system.

13. The computer-program product of claim 12, wherein the combined digital signal is indicative of one of a voice command, and the system executes one of the voice command as the operation to turn on a light.

14. The computer-program product of claim 9, wherein the computer-program product further comprising instructions for:
amplifying the analog audio signal by a first gain value; and
reducing the analog audio signal by a second gain value different from the first gain value.

15. The computer-program product of claim 14, wherein the first gain value is inversely proportional to an amplitude estimate of the analog audio signal.

16. The computer-program product of claim 14, wherein the second gain value is proportional to an amplitude estimate of the analog audio signal.

17. A method for processing an audio input signal, the method comprising:
amplifying an analog signal of the audio input signal into an amplified analog signal;
converting the amplified analog signal into an amplified digital signal;
reducing the amplified digital signal into a first digital signal;
reducing the analog signal into a reduced analog signal;
converting the reduced analog signal into a reduced digital signal;
amplifying the reduced digital signal into a second digital signal; and
combining the first digital signal and the second digital signal into a combined digital signal.

18. The method of claim 17 further comprising:
combining the first digital signal and the second digital signal using a root mean square (RMS) value of a frame signal.

19. The method of claim 18 further comprising:
processing the combined digital signal; and
responsive to processing the combined digital signal, performing an operation on a system.

20. The method of claim 19, wherein the combined digital signal is indicative of one of a voice command, and the system executes one of the voice command as the operation to provide a haptic feedback.
